(19) United States
(12) Patent Application Publication
(10) Pub. No.: US 2017/0358398 A1
(43) Pub. Date: Dec. 14, 2017

(54) PHOTOVOLTAIC DEVICE

(71) Applicant: OXFORD PHOTOVOLTAICS LIMITED, Oxfordshire (GB)

(72) Inventors: Nicola BEAUMONT, Oxfordshire (GB); Brett Akira KAMINO, Oxfordshire (GB); Benjamin LANGLEY, Oxfordshire (GB); Edward James William CROSSLAND, Oxfordshire (GB); Henry James SNAITH, Oxfordshire (GB)

(73) Assignee: Oxford Photovoltaics Limited, Oxfordshire (GB)

(21) Appl. No.: 15/527,188

(22) PCT Filed: Nov. 11, 2015
(86) PCT No.: PCT/GB2015/053422

§ 371 Date: May 16, 2017

(30) Foreign Application Priority Data
Nov. 18, 2014 (GB) 1420488.7

(51) Int. Cl. H01G 9/20; H01L 27/30; H01L 51/42; H01L 51/00

(52) U.S. Cl. CPC H01G 9/2009; H01L 51/4293; H01G 9/2068; H01L 27/302; H01L 51/422; H01L 51/0047; H01L 51/0048; H01L 51/0046

(57) ABSTRACT

There is provided a photovoltaic device that comprises a front electrode, a back electrode, and disposed between the front electrode and the back electrode, an electron transporter region comprising an electron transporter layer; a hole transporter region comprising a hole transporter layer, and a layer of perovskite semiconductor disposed between and in contact with the electron transporter layer and the hole transporter layer. The electron transporter region is nearest to the front electrode and the hole transporter region is nearest to the back electrode, and the electron transporter layer comprises any of a chalcogenide material and an organic material and has a thickness of at least 2 nm.

### FIELD OF THE INVENTION

The present invention relates to a photovoltaic device that provides for improved power generation performance under both light and load stressing conditions

### BACKGROUND OF THE INVENTION

Over the past forty years or so there has been an increasing realisation of the need to replace fossil fuels with more secure sustainable energy sources. The new energy supply must also have low environmental impact, be highly efficient and be easy to use and cost effective to produce. To this end, solar energy is seen as one of the most promising technologies, nevertheless, the high cost of manufacturing devices that capture solar energy, including high material costs, has historically hindered its widespread use.

Every solid has its own characteristic energy-band structure which determines a wide range of electrical characteristics. Electrons are able to transition from one energy band to another, but each transition requires a specific minimum energy and the amount of energy required will be different for different materials. The electrons acquire the energy needed for the transition by absorbing either a phonon (heat) or a photon (light). The term “band gap” refers to the energy difference range in a solid where no electron states can exist, and generally means the energy difference (in electron volts) between the top of the valence band and the bottom of the conduction band. The efficiency of a material used in a photovoltaic device, such as a solar cell, under normal sunlight conditions is a function of the band gap for that material. If the band gap is too high, most daylight photons cannot be absorbed; if it is too low, then most photons have much more energy than necessary to excite electrons across the band gap, and the rest will be wasted. The Shockley-Queisser limit refers to the theoretical maximum amount of electrical energy that can be extracted per photon of incoming light and is about 1.34 eV. The focus of much of the recent work on photovoltaic devices has been the quest for materials which have a band gap as close as possible to this maximum.

One class of photovoltaic materials that has attracted significant interest has been the hybrid organic-inorganic halide perovskites. Materials of this type form an ABX₃ crystal structure which has been found to show a favourable band gap, a high absorption coefficient and long diffusion lengths, making such compounds ideal as an absorber in photovoltaic devices. Early examples of hybrid organic-inorganic metal halide perovskite materials are reported by Kojima, A., et al, Organometal Halide Perovskites as Visible Light Sensitizers for Photovoltaic Cells. J. Am. Chem. Soc. 131(17), 6050-6051 (2009) in which such perovskites were used as the sensitizer in liquid electrolyte based photoelectrochemical cells. Kojima et al report that a highest obtained solar energy conversion efficiency (or power energy conversion efficiency, PCE) of 3.8%, although in this system the perovskite absorbers decayed rapidly and the cells dropped in performance after only 10 minutes.

Subsequently, Lee, M. et al, Efficient Hybrid Solar Cells Based on Meso-Superstructured Organometal Halide Perovskite. Science 338, 643-647 (2012) reported a “meso-superstructured solar cell” in which the liquid electrolyte was replaced with a solid-state hole conductor (or hole-transporting material, HTM), spiro-MeOTAD. Lee et al reported a significant increase in the conversion efficiency achieved, whilst also achieving greatly improved cell stability as a result of avoiding the use of a liquid solvent. In the examples described, CH₃NH₃Pbl₃ perovskite nanoparticles assume the role of the sensitizer within the photovoltaic cell, injecting electrons into a mesoscopic TiO₂ scaffold and holes into the solid-state HTM. Both the TiO₂ and the HTM act as selective contacts through which the charge carriers produced by photoexcitation of the perovskite nanoparticles are extracted.

Further work described in WO2013/171517 disclosed how the use of mixed-anion perovskites as a sensitizer/absorber in photovoltaic devices, instead of single-anion perovskites, results in more stable and highly efficient photovoltaic devices. In particular, this document discloses that the superior stability of the mixed-anion perovskites is highlighted by the finding that the devices exhibit negligible colour bleaching during the device fabrication process, whilst also exhibiting full sun power conversion efficiency of over 10%. In comparison, equivalent single-anion perovksites are relatively unstable, with bleaching occurring quickly when fabricating films from the single halide perovskites in ambient conditions.

More recently, WO2014/045021 described planar heterojunction (PHJ) photovoltaic devices comprising a thin film of a photoactive perovskite absorber disposed between n-type (electron transporting) and p-type (hole transporting) layers. Unexpectedly it was found that good device efficiencies could be obtained by using a compact (i.e. without effective/open porosity) thin film of the photoactive perovskite, as opposed to the requirement of a mesoporous composite, demonstrating that perovskite absorbers can function at high efficiencies in simplified device architectures.

### SUMMARY OF THE PRESENT INVENTION

The present inventors have recognised that, whilst perovskite-based photovoltaic devices can provide improved device stability and efficiency over other photovoltaic technologies, such devices demonstrate instability in their long-term power generation performance under both light and load stressing conditions.

The present invention therefore aims to provide perovskite-based photovoltaic device that produces stable power generation performance under both light and load stressing conditions. Stable power generation is defined here as still retaining 80% of the original maximum power output (voltage and current) post 1000 hours accelerated operation under full solar illumination (AM1.5G), full load and 85° C./85% temperature/humidity conditions.

According to a first aspect of the present invention there is provided a photovoltaic device comprising a front electrode, a back electrode and, disposed between the front electrode and the back electrode, an electron transporter region comprising an electron transporter layer, a hole transporter region comprising a hole transporter layer, and a layer of perovskite semiconductor disposed between and in contact with the electron transporter layer and the hole transporter layer. The electron transporter region is nearest to the front electrode and the hole transporter region is nearest to the back electrode, and wherein the electron transporter layer comprises any of a chalcogenide material and an organic material and has a thickness of at least 2 nm.

According to a second aspect of the present invention there is provided a multi-junction photovoltaic device comprising a front electrode, a back electrode and, disposed between the front electrode and the back electrode, an electron transporter region comprising an electron transporter layer, a hole transporter region comprising a hole transporter layer, and a layer of perovskite semiconductor disposed between and in contact with the electron transporter layer and the hole transporter layer. The electron transporter region is nearest to the back electrode and the hole transporter region is nearest to the front electrode; and wherein the electron transporter layer comprises any of a chalcogenide material and an organic material and has a thickness of at least 2 nm.

According to a third aspect of the present invention there is provided a method of producing a photovoltaic device. The method comprises the steps of (a) disposing an electron transport region comprising an electron transporter layer on a front electrode, (b) disposing a photoactive region comprising a layer of perovskite semiconductor on the electron transporter layer of the electron transport region, (c) disposing a hole transport region comprising a hole transporter layer on the photoactive region, and (d) disposing a back electrode on the hole transport region. In the method, the electron transporter layer comprises any of a chalcogenide material and an organic material and has a thickness of at least 2 nm.

According to a fourth aspect of the present invention there is provided a method of producing a multi-junction photovoltaic device. The method comprises the steps of (a) disposing an electron transport region comprising an electron transporter layer on a first region comprising a back electrode, (b) disposing a photoactive region comprising a layer of perovskite semiconductor on the electron transporter layer of the electron transport region, (c) disposing a hole transport region comprising a hole transporter layer on the photoactive region, and (d) disposing a front electrode on the hole transport region. In the method, the electron transporter layer comprises any of a chalcogenide material and an organic material and has a thickness of at least 2 nm.

The electron transporter layer may preferably have a thickness of 2 nm to 100 nm, and more preferably a thickness of 2 nm to 50 nm. The electron transporter layer may comprise a compact layer.

The electron transporter layer may comprise any of an n-type semiconductor material and an intrinsic semiconductor material, and the hole transporter layer may comprise any of a p-type semiconductor material and an intrinsic semiconductor material.

The electron transporter region may consist essentially of the electron transporter layer, and the electron transporter layer may then have a thickness of at least 5 nm, preferably may have a thickness of 5 nm to 100 nm, and more preferably may have a thickness of 5 nm to 50 nm.

The electron transporter layer may comprise a chalcogenide material, the chalcogenide material comprising one or more selected from metal sulphides, metal selenides, and metal tellurides. Alternatively, the electron transporter layer may comprise an organic semiconductor material, the organic semiconductor material comprising a fullerene or fullerene derivative. The electron transporter layer may then comprises an organic semiconductor material, the organic semiconductor material comprising one or more of C60, C70, C84, C60-PCBM, C70-PCBM, C84-PCBM and carbon nanotubes.

### BRIEF DESCRIPTION OF THE DRAWINGS

The present invention will now be more particularly described by way of example only with reference to the accompanying drawings, in which:

FIG. 1 illustrates schematically of the structure of (a) a conventional/regular perovskite photovoltaic device and (b) an inverted perovskite photovoltaic device as outlined in the description;

FIG. 2 illustrates schematically a photovoltaic device according to the present invention;

FIGS. 3a to 3d illustrate some exemplary embodiments of the present invention in which the electron transporter region comprises the electron transporter layer and an additional electron transporter layer;

FIG. 4 shows an example of the dark and light current-voltage results for a perovskite photovoltaic device according to the present invention, where the dark condition (thin line), light condition reverse (thick line) and light condition forward curve (dotted line) are shown;

FIG. 5 shows an example of a normalised max power vs. hours under accelerated environmental stressing for n-type 1: TiO2 and n-type 2: no TiO2 devices;

FIG. 6 shows an example of the normalised short circuit current (Jsc) and max power vs. hours under accelerated environmental stressing for a perovskite photovoltaic device of the present invention that makes use of an electron transporter region that consist of fullerenes; and

FIG. 7 illustrates schematically an example of a multi-junction photovoltaic device according to the present invention.

### DETAILED DESCRIPTION

### Definitions

The term “electrode”, as used herein, refers to a conductive material or object through which electric current enters or leaves an object, substance, or region. The term “negative electrode”, as used herein, refers to an electrode through which electrons leave a material or object (i.e. an electron collecting electrode). A negative electrode is typically referred to as an “anode”. The term “positive electrode”, as used herein, refers to an electrode through which holes leave a material or object (i.e. a hole collecting electrode). A positive electrode is typically referred to as a “cathode”. Within a photovoltaic device, electrons flow from the positive electrode/cathode to the negative electrode/anode, whilst holes flow from the negative electrode/anode to the positive electrode/cathode.

The term “front electrode”, as used herein, refers to the electrode provided on that side or surface of a photovoltaic device that it is intended will be exposed to sun light. The front electrode is therefore typically required to be transparent or semi-transparent so as to allow light to pass through the electrode to the photoactive layers provided beneath the front electrode. The term “back electrode”, as used herein, therefore refers to the electrode provided on that side or surface of a photovoltaic device that is opposite to the side or surface that it is intended will be exposed to sun light.

The term “electron transporter” refers to a region, layer or material through which electrons can easily flow and that will typically reflect holes (a hole being the absence of an electron that is regarded as a mobile carrier of positive charge in a semiconductor). Conversely, the term “hole transporter” refers to a region, layer or material through which holes can easily flow and that will typically reflect electrons.

The term “perovskite”, as used herein, refers to a material with a three-dimensional crystal structure related to that of CaTiO₃ or a material comprising a layer of material, which layer has a structure related to that of CaTiO₃. The structure of CaTiO₃ can be represented by the formula ABX₃, wherein A and B are cations of different sizes and X is an anion. In the unit cell, the A cations are at (0,0,0), the B cations are at (½, ½, ½) and the X anions are at (½, ½, 0). The A cation is usually larger than the B cation. The skilled person will appreciate that when A, B and X are varied, the different ion sizes may cause the structure of the perovskite material to distort away from the structure adopted by CaTiO₃ to a lower-symmetry distorted structure. The symmetry will also be lower if the material comprises a layer that has a structure related to that of CaTiO₃. Materials comprising a layer of perovskite material are well known. For instance, the structure of materials adopting the K₂NiF₄ type structure comprises a layer of perovskite material. The skilled person will appreciate that a perovskite material can be represented by the formula [A][B][X]₃, wherein [A] is at least one cation, [B] is at least one cation and [X] is at least one anion. When the perovskite comprise more than one A cation, the different A cations may distributed over the A sites in an ordered or disordered way. When the perovskite comprises more than one B cation, the different B cations may distributed over the B sites in an ordered or disordered way. When the perovskite comprise more than one X anion, the different X anions may distributed over the X sites in an ordered or disordered way. The symmetry of a perovskite comprising more than one A cation, more than one B cation or more than one X cation, will be lower than that of CaTiO₃.

The perovskite semiconductor employed in the present invention is typically one which is capable of (i) absorbing light, and thereby generating free charge carriers. Thus, the perovskite employed is typically a light-absorbing perovskite. Typically, the perovskite semiconductor used in the present invention is a photosensitizing material, i.e. a material which is capable of performing both photogeneration and charge (electron or hole) transportation.

The term “mixed-anion”, as used herein, refers to a compound comprising at least two different anions. The term “halide” refers to an anion of an element selected from Group 17 of the Periodic Table of the Elements, i.e., of a halogen. Typically, halide refers to a fluoride anion, a chloride anion, a bromide anion, an iodide anion or an astatide anion.

The term “metal halide perovskite”, as used herein, refers to a perovskite, the formula of which contains at least one metal cation and at least one halide anion. The term “organometal halide perovskite”, as used herein, refers to a metal halide perovskite, the formula of which contains at least one organic cation.

The term “chalcogenide”, as used herein, refers to materials that contain one or more of the elements Group 16 of the Periodic Table of the Elements, i.e. of the chalcogens (oxygen, sulphur, selenium or tellurium). Typically, chalcogenide refers to compounds that contain one or more of an oxide anion, a sulphide anion, a selenide anion and a telluride anion. The term “chalcogen”, as used herein, refers to an element selected from Group 16 of the Periodic Table of the Elements. Thus, the chalcogens include O, S, Se, and Te. Occasionally, the chalcogens are not taken to include O. Thus, the chalcogens may be understood to include S, Se and Te.

The term “organic material” takes its normal meaning in the art. Typically, an organic material refers to a material comprising one or more compounds that comprise a carbon atom. As the skilled person would understand it, an organic compound may comprise a carbon atom covalently bonded to another carbon atom, or to a hydrogen atom, or to a halogen atom, or to a chalcogen atom (for instance an oxygen atom, a sulfur atom, a selenium atom, or a tellurium atom). The skilled person will understand that the term “organic compound” does not typically include compounds that are predominantly ionic such as carbides, for instance.

The term “semiconductor”, as used herein, refers to a material with electrical conductivity intermediate in magnitude between that of a conductor and a dielectric. A semiconductor may be an n-type semiconductor, a p-type semiconductor or an intrinsic semiconductor.

The term “n-type semiconductor”, as used herein, refers to an extrinsic semiconductor with a larger concentration of electrons than holes. In n-type semiconductors, electrons are therefore majority carriers and holes are the minority carriers, and they are therefore electron transporting materials. N-type semiconductors are typically created by doping an intrinsic or a p-type semiconductor with electron donor impurities.

The term “p-type semiconductor”, as used herein, refers to an extrinsic semiconductor with a larger concentration of holes than electrons. In p-type semiconductors, holes are the majority carriers and electrons are the minority carriers, and they are therefore hole transporting materials. P-type semiconductors are typically created by doping an intrinsic or n-type semiconductor with electron acceptor impurities.

The term “band gap”, as used herein, refers to the energy difference between the top of the valence band and the bottom of the conduction band in a material. The skilled person may readily measure the band gap of a material without undue experimentation.

The term “layer”, as used herein, refers to any structure which is substantially laminar in form (for instance extending substantially in two perpendicular directions, but limited in its extension in the third perpendicular direction). A layer may have a thickness which varies over the extent of the layer. Typically, a layer has approximately constant thickness. The “thickness” of a layer, as used herein, refers to the average thickness of a layer. The thickness of layers may easily be measured, for instance by using microscopy, such as electron microscopy of a cross section of a film, or by surface profilometry for instance using a stylus profilometer.

The term “porous”, as used herein, refers to a material within which pores are arranged. Thus, for instance, in a porous material the pores are volumes within the scaffold where there is no material. Pores in a material may include “closed” pores as well as open pores. A closed pore is a pore in a material which is a non-connected cavity, i.e. a pore which is isolated within the material and not connected to any other pore and which cannot therefore be accessed by a fluid to which the material is exposed. An “open pore” on the other hand, would be accessible by such a fluid. The concepts of open and closed porosity are discussed in detail in J. Rouquerol et al., “Recommendations for the Characterization of Porous Solids”, Pure & Appl. Chem., Vol. 66, No. 8, pp. 1739-1758, 1994. Open porosity, therefore, refers to the fraction of the total volume of the porous material in which fluid flow could effectively take place. It therefore excludes closed pores. The term “open porosity” is interchangeable with the terms “connected porosity” and “effective porosity”, and in the art is commonly reduced simply to “porosity”. The term “without open porosity”, as used herein, therefore refers to a material with no effective porosity. The term “non-porous” as used herein, refers to a material without any porosity, i.e. without open porosity and also without closed porosity.

The term “compact layer”, as used herein, refers to a layer without effective/open porosity. In particular, the term “compact layer”, as used herein, refers to a layer without mesoporosity or macroporosity. A compact layer may sometimes have microporosity or nanoporosity.

The term “consisting essentially of” refers to a composition comprising the components of which it consists essentially as well as other components, provided that the other components do not materially affect the essential characteristics of the composition. Typically, a composition consisting essentially of certain components will comprise greater than or equal to 95 wt % of those components or greater than or equal to 99 wt % of those components.

Device Structure

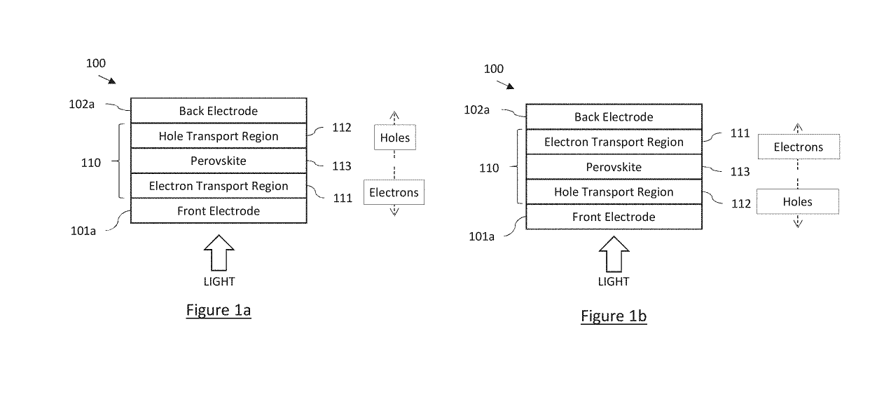

FIGS. 1a and 1b illustrate schematically separate structures for single junction photovoltaic devices 100 in which a photoactive region 110 comprises a photoactive perovskite material. In each of these embodiments, the photoactive region 110 comprises an electron transport region 111 comprising at least one electron transport layer, a hole transport region 112 comprising at least one hole transport layer, and a layer of the perovskite material 113 disposed between the electron transport region and the hole transport region.

The device illustrated in FIG. 1a has what is considered a regular structure for a perovskite-based single junction photovoltaic device wherein the front electrode 101 is in contact with the electron transport region 111 and the back electrode 102 is in contact with the hole transport region 112 (see, for example, Docampo, P et al. (2013) Efficient organometal trihalide perovskite planar-heterojunction solar cells on flexible polymer substrates. Nat Comms, 4). The front electrode 101 therefore functions as a negative (electron collecting) electrode, whilst the back electrode 102 functions as a positive (hole collecting) electrode.

By way of example, in the exemplary device structure illustrated in FIG. 1a the front electrode may comprise a transparent conductive oxide (TCO) such as tin-doped indium-oxide (ITO), fluorine doped tin oxide (FTO) etc., the electron transport region may comprise one or more layers of electron transport material, the hole transport region may comprise one or more layers of hole transport material, and the back electrode may comprise a high work function metal such as gold (Au) silver (Ag), nickel (Ni), palladium (Pd), platinum (Pt) or aluminium (Al).

In contrast, the device illustrated in FIG. 1b has what is considered to be an inverted structure for a perovskite-based single junction photovoltaic device wherein the front electrode 101 is in contact with the hole transport region 112 and the back electrode 102 is in contact with the electron transport region 111. The front electrode 101 therefore functions as positive (hole collecting) electrode, whilst the back electrode 102 functions as a negative (electron collecting) electrode.

By way of example, in the exemplary device structure illustrated in FIG. 1b the front electrode may comprise a transparent conductive oxide (TCO) such as tin-doped indium-oxide (ITO), fluorine doped tin oxide (FTO) etc., the hole transport region may comprise one or more layers of hole transport material, the electron transport region may comprise one or more layers of electron transport material, and the back electrode may comprise a high work function metal such as gold (Au) silver (Ag), nickel (Ni), palladium (Pd), platinum (Pt) or aluminium (Al).

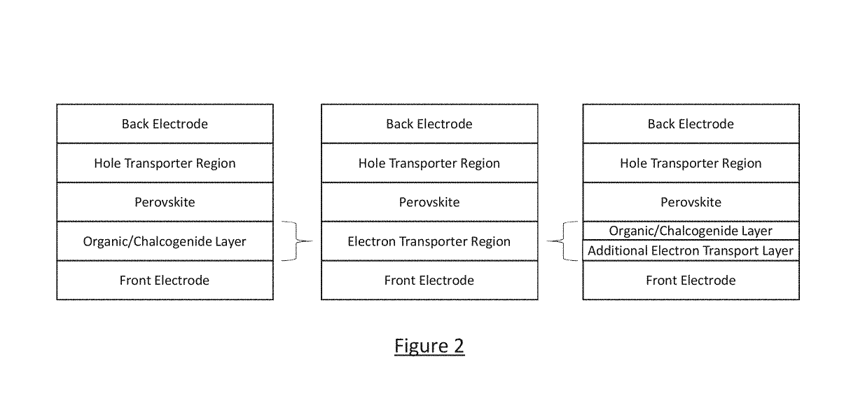

FIG. 2 illustrates schematically a photovoltaic device according a first aspect of the present invention. The photovoltaic device comprises a front electrode, a back electrode and, disposed between the front electrode and the back electrode, an electron transporter region comprising an electron transporter layer, a hole transporter region comprising a hole transporter layer, and a layer of perovskite semiconductor disposed between and in contact with the electron transporter layer and the hole transporter layer. Within the photovoltaic device the electron transporter region is nearest to the front electrode and the hole transporter region is nearest to the back electrode, and the electron transporter layer comprises any of a chalcogenide material and an organic material and has a thickness of at least 2 nm. As used herein, the term “thickness” refers to the average thickness of a component of the device. A thickness of at least 2 nm is required in order to sufficiently inhibit photo-degradation of the photovoltaic device). For similar reasons it is also preferably that the electron transporter layer is provided as a compact layer.

Preferably, the electron transporter layer has a thickness of 2 nm to 100 nm, and more preferably has a thickness of 2 nm to 50 nm. A thickness of greater than 100 nm would significantly increase the absorption losses and is also highly likely to create a charge barrier, both of which would significantly impact on the efficiency of the device. A thickness of up to 50 nm is considered to provide an optimum balance between ensuring inhibition of photo-degradation and minimising absorption and/or charge collection losses.

The electron transporter layer may comprise any of an n-type semiconductor material and an intrinsic semiconductor material, and the hole transporter layer may comprise any of a p-type semiconductor material and an intrinsic semiconductor material.

The perovskite is preferably an organometal halide perovskite semiconductor, or a mixed-anion perovskite. Examples of such perovskite semiconductors are given in WO2013/171517 and WO2014/045021.

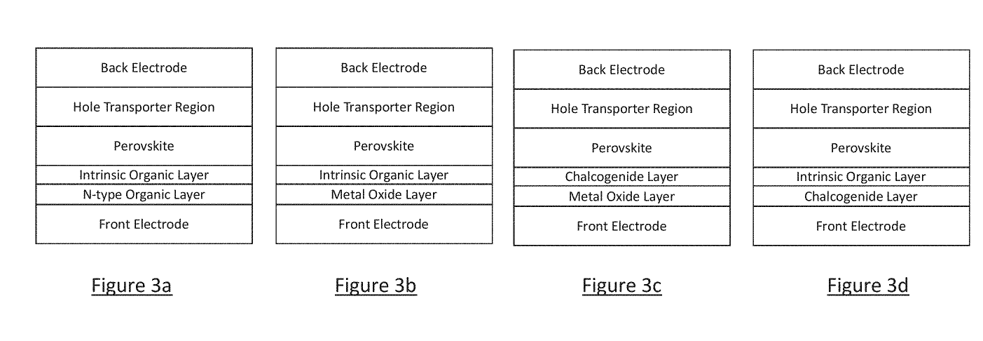

As illustrated in FIG. 2, the electron transporter region can consist of the electron transporter layer, or can comprise the electron transporter layer (i.e. the chalcogenide/organic material layer) and an additional electron transporter layer. In this regard, FIGS. 3a to 3d illustrate some exemplary embodiments of the present invention in which the electron transporter region comprises the electron transporter layer and an additional electron transporter layer. All of these embodiments include electron transporter regions that either do not contain any metal oxide (e.g. titania) or where the perovskite layer is not in direct contact with a metal oxide. In this way, any photocatalysis reaction products (e.g. free radical hydroxyl) do not degrade the perovskite semiconductor layer.

The present inventors have surprisingly found that by replacing the compact TiO₂ layer that is typically used as the electron transporter layer within conventional photovoltaic devices with either a chalcogenide material or an organic material, stable power generation performance under both light and load stressing conditions can be achieved. In particular, photovoltaic devices employing such an electron transporter layer in contact with the photoactive perovskite semiconductor can survive for 100s of hours under simulated full spectrum light. This is exceptionally surprising, as the person skilled in the art would expect a metal oxide, such as TiO₂, to be much more stable than an organic material, such as C60, since the carbon-carbon bonds in organic molecules can be broken by absorption of UV light. Therefore it is all the more remarkable that photovoltaic devices incorporating an electron transporter layer in contact with the photoactive perovskite semiconductor that consists of a fundamentally less stable organic material are themselves more stable once sealed from atmospheric oxygen.

In this regard, TiO₂ has been considered the foremost electron transporter material in dye-sensitized solar cells for the last 23 years and has not been replaced. Moreover, TiO₂ has been employed in some of the most efficient perovskite solar cells to-date, either as an n-type compact layer (see WO2014/045021) or also as a mesoporous layer (see Kojima et al, Lee et al, and WO2013/171517). However, the present inventors believe that the problem with the majority of metal oxides is that they are photocatalytic in nature (i.e. they generate free radical products (hydroxyls) under sunlight), and that these free radicals can ‘poison’ perovskite semiconductor materials.

Therefore, by making use of a chalcogenide or organic material as the electron transporter layer in contact with the photoactive perovskite semiconductor to inhibit photocatalysis, the photovolatic devices described herein achieve stable power generation close to the reverse curve efficiency, and device stability under full illumination and load is greatly improved.

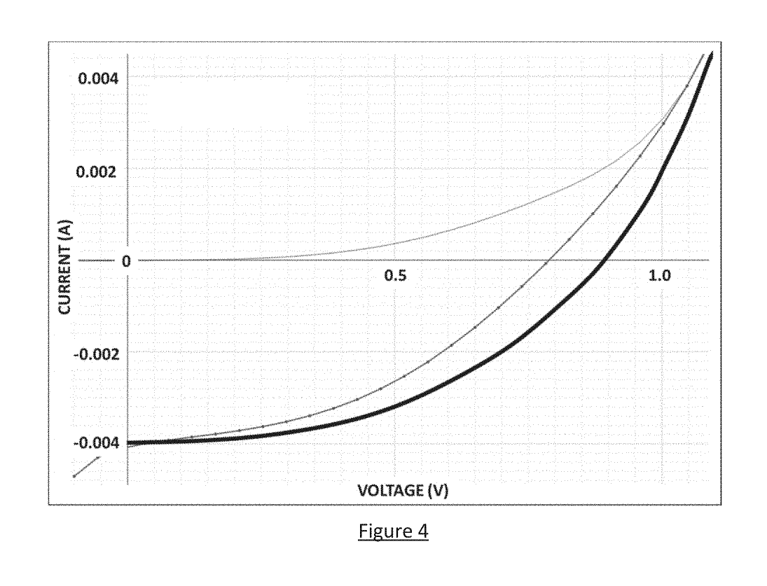

FIG. 4 shows an example of the current-voltage results for a perovskite photovoltaic device according to the present invention. This example shows the dark and light current-voltage (I-V) curves of a typical perovskite photovoltaic device of the present invention when making use of an electron transporter region that consist of fullerenes compared to that of TiO₂. Here the dark condition (thin line), light condition reverse (thick line) and light condition forward curve (dotted line) are shown. These current-voltage results demonstrate that stable efficiency and power can be achieved when making use of an electron transporter region that consist of fullerenes instead of TiO₂. An important factor to note is the stable power output falls onto the reverse (higher performing) curve, whereas for a photovoltaic device that makes use of TiO₂ as an electron transporter region this falls on the forward (lower performing) curve.

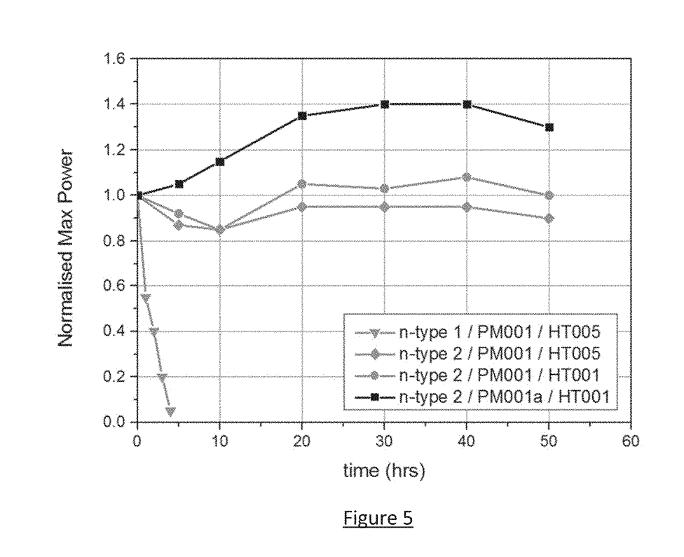

FIG. 5 shows an example of a normalised max power vs. hours under accelerated environmental stressing for an electron transporter region consisting of TiO₂ (labelled n-type 1) and an electron transporter region consisting of a fullerene (e.g. PCBM) (labelled n-type 2). This example highlights the major problem with perovskite photovoltaic device stability when using photocatalytic TiO₂; where under 1-sun light-soaking conditions and under load the solar cell performance rapidly decreases to zero within 5 hours. When TiO₂ is replaced by a fullerene (e.g. PCBM) little or no decrease in power output is observed up to 50 hours operation.

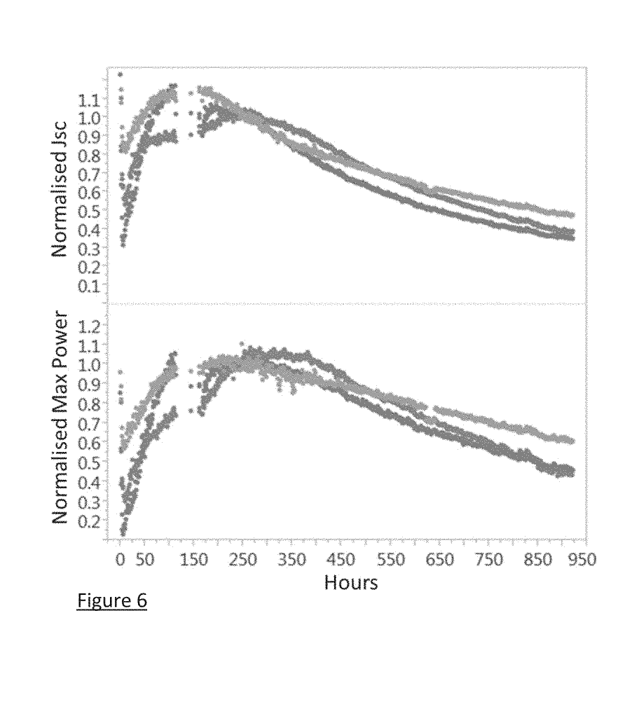

FIG. 6 shows an example of the normalised short circuit current (Jsc) and max power vs. hours under accelerated environmental stressing for a perovskite photovoltaic device of the present invention that makes use of an electron transporter region that consist of fullerenes. The normalised max power vs. time results under accelerated environmental stressing (1-sun light soaking at 50° C. under load) again demonstrate the significant improvement that can be achieved by photovoltaic devices of the present invention, as the efficiency only begins to decrease post lamination failure at 300-350 hours.

Furthermore, the present inventors have also determined that by making use of a multi-layer electron transporter region between the photoactive perovskite semiconductor and the front electrode, as is illustrated in the examples of FIGS. 3a to 3d, there is improved charge collection at their interface through improved charge transport and extraction.

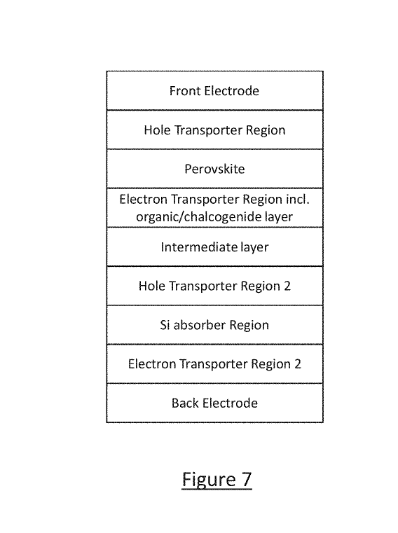

Whilst this aspect of the present invention described above in relation to FIGS. 2 and 3a to 3d relate to single-junction devices, in an addition aspect of the present invention, the electron transporter region is also applicable to multi-junction photovoltaic devices. In this regard, a multi-junction perovskite photovoltaic device comprises a photovoltaic sub-cell and one or more additional photovoltaic sub-cells, wherein the photovoltaic sub-cell comprises the electron transporter region, the hole transporter region and the layer of perovskite semiconductor. The photovoltaic sub-cell is then connected to an additional photovoltaic sub-cell by an intermediate layer. Similarly, if the photovoltaic device comprises two or more additional photovoltaic sub-cells, then each of the additional photovoltaic sub-cells is connected to another of the additional photovoltaic sub-cells by an intermediate layer. However, in a multi-junction photovoltaic device, due to the band-gap of the perovskite, the perovskite sub-cell will typically be the top sub-cell (i.e. that is adjacent the front electrode) and is most conveniently deposited over an additional photovoltaic sub-cell. Consequently, in a multi-junction photovoltaic device, the above described electron transport region is nearest to the back electrode, as the electron transport region is deposited before the photoactive region comprising the perovskite material, and the hole transporter region is nearest to the front electrode, the hole transport region is deposited after the photoactive region comprising the perovskite material. By way of example, FIG. 7 illustrates schematically an example of a multi-junction photovoltaic device that has a tandem structure, in which a perovskite-based photovoltaic sub-cell is combined with a Si photovoltaic sub-cell.

It will be appreciated that individual items described above may be used on their own or in combination with other items shown in the drawings or described in the description and that items mentioned in the same passage as each other or the same drawing as each other need not be used in combination with each other.

Furthermore, although the invention has been described in terms of preferred embodiments as set forth above, it should be understood that these embodiments are illustrative only. Those skilled in the art will be able to make modifications and alternatives in view of the disclosure which are contemplated as falling within the scope of the appended claims.

For example, those skilled in the art will appreciate that whilst the above-described embodiments of the invention all relate to photovoltaic devices, aspects of the invention may be equally applicable to other optoelectronic devices. In this regard, the term “optoelectronic devices” includes photovoltaic devices, photodiodes (including solar cells), photodetectors (including x-ray detectors), phototransistors, photomultipliers, photoresistors, and light emitting diodes etc. In particular, whilst in the above-described embodiments the photoactive perovskite material is used as a light absorber/photosensitizer, it may also function as light emitting material by accepting charge, both electrons and holes, which subsequently recombine and emit light.

By way of further example, those skilled in the art will appreciate that whilst illustrated embodiments of the invention all relate to photovoltaic devices in which the layer of the perovskite material is shown as a compact layer (i.e. a layer without open porosity), and forming a planar heterojunction with the electron and hole transport regions, aspects of the invention may be equally applicable to other arrangements of the photoactive region. In particular, the photoactive region comprising the layer of perovskite material could also have what has been referred to as an extremely thin absorber (ETA) cell architecture in which an extremely thin layer of the light absorbing perovskite material is provided at the interface between nanostructured, interpenetrating n-type (e.g. TiO2) and p-type semiconductors (e.g. HTM). Alternatively, the photoactive region comprising the layer of perovskite material could have what has been referred to as a meso-superstructured solar cell (MSSC) architecture in which an extremely thin layer of the light absorbing perovskite material is provided on a mesoporous insulating scaffold material.

In a further alternative, the photoactive region could comprise a layer of the perovskite material wherein the perovskite material fills the pores of a porous scaffold material and forms a capping layer of the perovskite material over the porous scaffold material, wherein the capping layer of the perovskite material is not infiltrated by the porous scaffold material. In a yet further alternative, the photoactive region could comprise a layer of the perovskite wherein the perovskite material is itself porous. A charge transporting material then fills the pores of porous region of perovskite material and forms a capping layer over the porous perovskite material. In this regard, the capping layer of charge transporting material consists of a layer of the charge transporting material without open porosity.

1. A photovoltaic device comprising:
a front electrode;
a back electrode; and
disposed between the front electrode and the back electrode:
an electron transporter region comprising an electron transporter layer;
a hole transporter region comprising a hole transporter layer; and
a layer of perovskite semiconductor disposed between and in contact with the electron transporter layer and the hole transporter layer;
wherein the electron transporter region is nearest to the front electrode and the hole transporter region is nearest to the back electrode, and wherein the electron transporter layer comprises any of a chalcogenide material and an organic material and has a thickness of at least 2 nm.

2. The photovoltaic device of claim 1, wherein the electron transporter layer has a thickness of 2 nm to 100 nm, and more preferably has a thickness of 2 nm to 50 nm.

3. The photovoltaic device of claim 1, wherein electron transporter layer comprises a compact layer.

4. The photovoltaic device of claim 1, wherein the electron transporter layer comprises any of an n-type semiconductor material and an intrinsic semiconductor material, and the hole transporter layer comprises any of a p-type semiconductor material and an intrinsic semiconductor material.

5. The photovoltaic device of claim 1, wherein the electron transporter region further comprises an additional electron transporter layer.

6. (canceled)

7. (canceled)

8. The photovoltaic device of claim 1, wherein the electron transporter region consists essentially of the electron transporter layer, and the electron transporter layer has a thickness of at least 5 nm, preferably has a thickness of 5 nm to 100 nm, and more preferably has a thickness of 5 nm to 50 nm.

9. (canceled)

10. The photovoltaic device of claim 1, wherein the electron transporter layer comprises an organic semiconductor material, the organic semiconductor material comprising a fullerene or fullerene derivative.

11. The photovoltaic device of claim 10, wherein the electron transporter layer comprises an organic semiconductor material, the organic semiconductor material comprising one or more of C60, C70, C84, C60-PCBM, C70-PCBM, C84-PCBM and carbon nanotubes.

12. (canceled)

13. A multi junction photovoltaic device comprising:
a front electrode;
a back electrode; and
disposed between the front electrode and the back electrode:
an electron transporter region comprising an electron transporter layer;
a hole transporter region comprising a hole transporter layer; and
a layer of perovskite semiconductor disposed between and in contact with the electron transporter layer and the hole transporter layer;
wherein the electron transporter region is nearest to the back electrode and the hole transporter region is nearest to the front electrode; and wherein the electron transporter layer comprises any of a chalcogenide material and an organic material and has a thickness of at least 2 nm.

14. The multi junction photovoltaic device of claim 13, wherein the electron transporter layer has a thickness of 2 nm to 100 nm, and more preferably has a thickness of 2 nm to 50 nm.

15. The multi junction photovoltaic device of claim 13, wherein electron transporter layer comprises a compact layer.

16. The multi junction photovoltaic device of claim 13, wherein the electron transporter layer comprises any of an n-type semiconductor material and an intrinsic semiconductor material, and the hole transporter layer comprises any of a p-type semiconductor material and an intrinsic semiconductor material.

17. The multi junction photovoltaic device of claim 13, wherein the electron transporter region further comprises an additional electron transporter layer.

18. (canceled)

19. (canceled)

20. The multi junction photovoltaic device of claim 13, wherein the electron transporter region consists essentially of the electron transporter layer, and the electron transporter layer has a thickness of at least 5 nm, preferably has a thickness of 5 nm to 100 nm, and more preferably has a thickness of 5 nm to 50 nm.

21. (canceled)

22. The multi junction photovoltaic device of claim 13, wherein the electron transporter layer comprises an organic semiconductor material, the organic semiconductor material comprising a fullerene or fullerene derivative.

23. The multi junction photovoltaic device of claim 22, wherein the electron transporter layer comprises an organic semiconductor material, the organic semiconductor material comprising one or more of C60, C70, C84, C60-PCBM, C70-PCBM, C84-PCBM and carbon nanotubes.

24. The multi junction photovoltaic device of claim 13, wherein the photovoltaic device comprises a photovoltaic sub-cell and one or more additional photovoltaic sub-cells, wherein the photovoltaic sub-cell comprises the electron transporter region, the hole transporter region and the layer of perovskite semiconductor.

25. (canceled)

26. (canceled)

27. (canceled)

28. (canceled)

29. (canceled)

30. A method of producing a photovoltaic device, the method comprising:
(a) disposing an electron transport region comprising an electron transporter layer on a front electrode;
(b) disposing a photoactive region comprising a layer of perovskite semiconductor on the electron transporter layer of the electron transport region;
(c) disposing a hole transport region comprising a hole transporter layer on the photoactive region; and
(d) disposing a back electrode on the hole transport region;
wherein the electron transporter layer comprises any of a chalcogenide material and an organic material and has a thickness of at least 2 nm.

31. (canceled)

32. The method of claim 30, wherein the step of disposing an electron transport region comprises depositing an electron transporter layer having a thickness of 2 nm to 100 nm, and more preferably having a thickness of 2 nm to 50 nm.

33. The method of claim 30, wherein the step of disposing an electron transport region comprises depositing an electron transporter layer as a compact layer.

34. The method of claim 30, wherein the electron transporter layer comprises any of an n-type semiconductor material and an intrinsic semiconductor material, and the hole transporter layer comprises any of a p-type semiconductor material and an intrinsic semiconductor material.

35. The method of claim 30, wherein the electron transporter region further comprises an additional electron transporter layer.

36. (canceled)

37. (canceled)

38. The method of claim 30, wherein the electron transporter region consists essentially of the electron transporter layer,

39. The method of claim 38, wherein the step of disposing an electron transport region consists of depositing an electron transporter layer having a thickness of at least 5 nm, preferably having a thickness of 5 nm to 100 nm, and more preferably having a thickness of 5 nm to 50 nm.

40. (canceled)

41. The method of claim 30, wherein the electron transporter layer comprises an organic semiconductor material, the organic semiconductor material comprising a fullerene or fullerene derivative.

42. The method of claim 41, wherein the electron transporter layer comprises an organic semiconductor material, the organic semiconductor material comprising one or more of C60, C70, C84, C60-PCBM, C70-PCBM, C84-PCBM and carbon nanotubes.

43. A method of producing a multi junction photovoltaic device, the method comprising:
(a) disposing an electron transport region comprising an electron transporter layer on a first region comprising a back electrode;
(b) disposing a photoactive region comprising a layer of perovskite semiconductor on the electron transporter layer of the electron transport region;
(c) disposing a hole transport region comprising a hole transporter layer on the photoactive region; and
(d) disposing a front electrode on the hole transport region;
wherein the electron transporter layer comprises any of a chalcogenide material and an organic material and has a thickness of at least 2 nm.

44. The method of claim 43, wherein the multi junction photovoltaic device comprises a photovoltaic sub-cell and one or more additional photovoltaic sub-cells, wherein the photovoltaic sub-cell comprises the electron transporter region, the hole transporter region and the layer of perovskite semiconductor.

45. (canceled)

46. The method of claim 43, wherein the step of disposing an electron transport region comprises depositing an electron transporter layer having a thickness of 2 nm to 100 nm, and more preferably having a thickness of 2 nm to 50 nm.

47. The method of claim 43, wherein the step of disposing an electron transport region comprises depositing an electron transporter layer as a compact layer.

48. The method of claim 43, wherein the electron transporter layer comprises any of an n-type semiconductor material and an intrinsic semiconductor material, and the hole transporter layer comprises any of a p-type semiconductor material and an intrinsic semiconductor material.

49. The method of claim 43, wherein the electron transporter region further comprises an additional electron transporter layer.

50. (canceled)

51. (canceled)

52. The method of claim 43, wherein the electron transporter region consists essentially of the electron transporter layer.

53. The method of claim 52, wherein the step of disposing an electron transport region consists of depositing an electron transporter layer having a thickness of at least 5 nm, preferably having a thickness of 5 nm to 100 nm, and more preferably having a thickness of 5 nm to 50 nm.

54. (canceled)

55. The method of claim 43, wherein the electron transporter layer comprises an organic semiconductor material, the organic semiconductor material comprising a fullerene or fullerene derivative.

56. The method of claim 55, wherein the electron transporter layer comprises an organic semiconductor material, the organic semiconductor material comprising one or more of C60, C70, C84, C60-PCBM, C70-PCBM, C84-PCBM and carbon nanotubes.
